(19) United States
(12) Patent Application Publication
(10) Pub. No.: US 2025/0204136 A1
(43) Pub. Date: Jun. 19, 2025

(54) DISPLAY DEVICE

(71) Applicant: FUJIFILM Corporation, Tokyo (JP)

(72) Inventors: Haruka SANO, Kanagawa (JP); Makoto ISHIGURO, Kanagawa (JP)

(73) Assignee: FUJIFILM Corporation, Tokyo (JP)

(21) Appl. No.: 19/072,293

(22) Filed: Mar. 6, 2025

Related U.S. Application Data
(63) Continuation of application No. PCT/JP2023/030806, filed on Aug. 25, 2023.

(30) Foreign Application Priority Data
Sep. 7, 2022 (JP) 2022-142397

(51) Int. Cl. H10H 29/856; H01L 25/075; H10H 29/24; H10H 29/80

(52) U.S. Cl. CPC H10H 29/856; H10H 29/24; H10H 29/882; H01L 25/0753

(57) ABSTRACT

There is provided a display device including a film including a layer that selectively reflects at least a part of light in a wavelength range of 380 nm to 780 nm to exhibit a structural color, and a micro LED display.

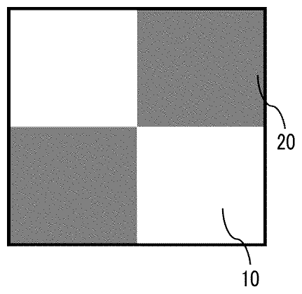

### CROSS-REFERENCE TO RELATED APPLICATIONS

This application is a continuation application of International Application No. PCT/JP2023/030806, filed Aug. 25, 2023, the disclosure of which is incorporated herein by reference in its entirety. Further, this application claims priority from Japanese Patent Application No. 2022-142397, filed Sep. 7, 2022, the disclosure of which is incorporated herein by reference in its entirety.

### BACKGROUND OF THE INVENTION

### 1. Field of the Invention

The present disclosure relates to a display device.

### 2. Description of the Related Art

A display device that displays an image on a display is usually observed in black in an image non-display state. Various performances are required for a display device, and one of the performances is excellent designability in an image non-display state.

In response to the above-described demand, JP2021-178475A discloses a method of producing a film in which a design layer is formed on a surface of a support by printing or the like, and disposing the film on an observer side of a display.

### SUMMARY OF THE INVENTION

In recent years, in order to achieve a high definition of a display device, a micro light emitting diode (LED) has been started to be mounted on a display instead of a light emitting diode (LED) in the related art.

In a case where the film described in JP2021-178475A is disposed on the observer side of a display on which micro LEDs are mounted, light from the micro LEDs is blocked by the design layer, and characters displayed on the display may be blurred or difficult to recognize, and thus there is room for improvement in visibility of the display.

In order to improve the visibility of the display, it is also considered to increase the distance between the design layers, but in this case, the designability in an image non-display state is deteriorated.

An object to be achieved by one embodiment of the present disclosure is to provide a display device having excellent visibility of a display in an image display state and excellent designability in an image non-display state.

The present disclosure includes the following aspects.

<1> A display device comprising:
a film including a layer that selectively reflects at least a part of light in a wavelength range of 380 nm to 780 nm to exhibit a structural color; and
a micro LED display.

<2> The display device according to <1>, further comprising: a λ/4 retardation plate; and a polarizer, in which the film, the λ/4 retardation plate, the polarizer, and the micro LED display are provided in this order.

<3> The display device according to <1> or <2>, in which the layer exhibiting the structural color is a cholesteric liquid crystal layer.

<4> The display device according to any one of <1> to <3>, in which the layer exhibiting the structural color has a plurality of regions having different maximum peak wavelengths of reflectivity in a plane.

<5> The display device according to any one of <1> to <4>, in which the film further includes a support and an undercoat layer, and the support, the undercoat layer, and the layer exhibiting structural color are provided in this order.

<6> The display device according to <5>, in which the layer exhibiting the structural color is a cholesteric liquid crystal layer, and the undercoat layer is a layer imparting light scattering properties to the cholesteric liquid crystal layer.

<7> The display device according to <5> or <6>, in which a surface energy of the undercoat layer is 30 mN/m² to 60 mN/m².

<8> The display device according to any one of <1> to <7>, in which a thickness of the layer exhibiting the structural color is 0.3 μm to 15 μm.

<9> The display device according to any one of <1> to <8>, in which the film is a decorative film.

According to one embodiment of the present disclosure, it is possible to provide a display device having excellent visibility of a display in an image display state and excellent designability in an image non-display state.

### BRIEF DESCRIPTION OF THE DRAWINGS

The FIGURE is a front view of a patterning mask used in Examples.

### DESCRIPTION OF THE PREFERRED EMBODIMENTS

Hereinafter, an embodiment which is an example of the present invention will be described. These descriptions and examples are only illustrative of the embodiments and do not limit the scope of the invention.

In a numerical range described in a stepwise manner in the present disclosure, an upper limit or a lower limit described in one numerical range may be replaced with an upper limit or a lower limit in another numerical range described in a stepwise manner. Further, in a numerical range described in the present disclosure, an upper limit or a lower limit described in the numerical range may be replaced with a value described in an example. In the present disclosure, “to” is used to refer to a meaning including numerical values denoted before and after “to” as a lower limit value and an upper limit value, respectively.

Each component may contain a plurality of kinds of substances corresponding thereto.

In a case where the amount of each component in a composition is referred to, and in a case where a plurality of substances corresponding to each component in the composition are present, it means the total amount of a plurality of substances present in the composition, unless otherwise specified.

In the present disclosure, the “structural color” is a color generated by an interaction between a wavelength of visible light or a fine structure equal to or smaller than a wavelength of visible light and light, such as interference, diffraction, refraction, and scattering. The structural color is also widely observed in nature, such as an iris of a fish, feathers of a peacock, a shell of an insect, a morpho butterfly, a pearl, and a gloss of an opal.

In the present disclosure, the term “micro LED display” means a display equipped with a micro LED. In addition, the “micro LED” means an LED in which a length of one side of an LED chip is 100 μm or less.

In the present disclosure, the term “layer” includes, a case where a layer is formed on the entire region and a case where a layer is formed only on a part of the region, when a region in which the layer is present is observed.

In the present disclosure, “(meth)acrylate” represents acrylate and methacrylate, and “(meth)acrylic” represents acrylic and methacrylic.

In the present disclosure, a combination of two or more preferred aspects is a more preferred aspect.

In the present disclosure, in a case where an embodiment is described with reference to the accompanying drawings, the configuration of the embodiment is not limited to the configuration shown in the drawings. In addition, the sizes of the members in each drawing are conceptual, and the relative size relationships between the members are not limited thereto.

### [Display Device]

A display device according to the present disclosure includes a film including a layer that selectively reflects at least a part of light in a wavelength range of 380 nm to 780 nm to exhibit a structural color, and a micro LED display.

The display device of the present disclosure has excellent visibility of the display in the image display state and excellent designability in the image non-display state. The reason why the above-described effects are exhibited is not clear, but is assumed as follows.

It is presumed that the film of the display device of the present disclosure selectively reflects at least a part of light in a wavelength range of 380 nm to 780 nm, and the layer exhibiting the structural color blocks a part of light emitted from the micro LED but transmits most of light, and thus the visibility of the display in an image display state is excellent. In addition, it is presumed that the film included in the image display device includes a layer exhibiting the structural color, and thus the designability in the image non-display state is excellent.

From the viewpoint of visibility of the display in the image display state, it is preferable that the display device of the present disclosure further includes a V4 retardation plate and a polarizer, and more preferable that the display device includes the V4 retardation plate, the polarizer, and the micro LED display in this order.

### (Film)

The film includes a layer (hereinafter, also referred to as a “specific layer”) that selectively reflects at least a part of light in a wavelength range of 380 nm to 780 nm to exhibit a structural color.

It is preferable that the film further includes a support and an undercoat layer, and for example, can include the support, the undercoat layer, and the specific layer in this order.

In one embodiment, the film included in the display device of the present disclosure is a decorative film.

From the viewpoint of visibility of the display in the image display state, in at least a part in a plane of the film, a transmittance of one of the dextrorotatory circularly polarized light or the levorotatory circularly polarized light is preferably 80% or more, more preferably 85% or more, still more preferably 90% or more, particularly preferably 95% or more, and most preferably 100%.

From the viewpoint of designability in an image non-display state, a maximum integral reflectivity in a wavelength range of 380 nm to 780 nm in at least a part of a plane of the film is preferably 30% or less, more preferably 25% or less, and still more preferably 20% or less.

In the present disclosure, the transmittance of one circularly polarized light is measured by the following method. The total light transmittance of the film is measured using a haze meter (NDH5000, manufactured by Nippon Denshoku Industries Co., Ltd.) such that light is incident from the liquid crystal layer side of the film through a polarizing plate that converts the light into the circularly polarized light.

### —Specific Layer—

The specific layer selectively reflects at least a part of light in a wavelength range of 380 nm to 780 nm.

In the specific layer, a reflectivity for at least a part of the light in a wavelength range of 380 nm to 780 nm is preferably greater than 0%.

In the specific layer, it is preferable that a selective reflection wavelength is present in a wavelength range of 380 nm to 780 nm.

The “selective reflection wavelength” refers to an average value of two wavelengths indicating a half-value transmittance (T½, unit: %) represented by the following expression, in a case where a minimum value of a transmittance in a target object is defined as Tmin (%).

Half-value transmittance T½=100−(100−Tmin)/2 Expression:

The specific layer exhibits a structural color. It is determined whether or not the specific layer exhibits the structural color by irradiating the specific layer with light (specifically, a white light source) and checking a tint of the surface. It can also be confirmed whether or not the specific layer exhibits the structural color by the fact that the maximum peak wavelength in a case where light is received at an angle that is a specular reflection direction with respect to a certain specific incidence angle varies depending on an incidence angle and a light-receiving angle.

From the viewpoint of designability in the image non-display state, it is preferable that the specific layer has a plurality of regions having different maximum peak wavelengths of reflectivity in a plane. It is preferable that the plurality of regions are present in a plane of a cholesteric liquid crystal layer.

It can be confirmed whether or not the specific layer has a plurality of regions in which the photoisomerization ratios of the photoisomerization optically active compound are different from each other by whether or not the film including the cholesteric liquid crystal layer includes a plurality of regions having different tint. Here, the plurality of regions having different tints includes not only a colored region that reflects light in a visible range but also a colorless region that reflects infrared light or ultraviolet light.

In a case where the confirmation is not possible by visual observation, it can also be confirmed whether or not the specific layer has a plurality of regions in which the photoisomerization ratios of the photoisomerization optically active compound are different from each other by the following method.

Reflection spectra in a wavelength range of 380 nm to 1500 nm are measured in the plurality of regions of the film having the specific layer by using a multi-channel spectroscope (PMA-12, manufactured by Hamamatsu Photonics K.K.).

In a case where a difference between a maximum wavelength λ1 in a region where the maximum wavelength is the smallest and a maximum wavelength λ2 in a region where the maximum wavelength is the largest is 10 nm or more, it is considered that the cholesteric liquid crystal layer has the plurality of regions where the photoisomerization ratios of the photoisomerization optically active compound are different from each other. The difference between λ1 and λ2 is represented by an absolute value (that is, |λ1−λ2|).

From the viewpoint of designability in the image non-display state, a thickness of the specific layer is preferably 0.3 μm to 15 μm, more preferably 0.5 μm to 9 μm, and still more preferably 0.6 μm to 7 μm.

Examples of the specific layer are not particularly limited, but suitable examples thereof include an organic multilayer film layer, an inorganic multilayer film layer, and a cholesteric liquid crystal layer. Among these, from the viewpoint of visibility of the display in the image display state, the cholesteric liquid crystal layer is particularly preferable as the specific layer.

The film may include two or more specific layers, and in this case, helical pitches of the cholesteric liquid crystal structures of the respective layers may be the same or different from each other.

### ——Organic Multilayer Film Layer——

Suitable examples of the organic multilayer film layer include a layer having a structure in which a resin layer having a high refractive index (hereinafter, also referred to as a “layer A”) and a resin layer having a low refractive index (hereinafter, also referred to as a “layer B”) are laminated.

From a viewpoint of visibility of a light tone and suppression of a change in tint depending on a visual angle, the above-described layer B is preferably a layer having a refractive index lower than that of the above-described layer A by 0.1 or more, more preferably a layer having a refractive index lower than that of the above-described layer A by 0.15 or more, still more preferably a layer having a refractive index lower than that of the above-described layer A by 0.2 or more, particularly preferably a layer having a refractive index lower than that of the above-described layer A by 0.25 or more, and most preferably a layer having a refractive index lower than that of the above-described layer A by 0.25 or more and 0.60 or less.

From the viewpoint of visibility of a light tone and suppression of a change in tint depending on a visual angle, the refractive index of the above-described layer A is preferably 1.5 or more, more preferably 1.6 or more, still more preferably 1.65 or more, and particularly preferably 1.70 or more. In addition, the upper limit of the refractive index of the layer A is preferably 2.3 or less and more preferably 1.9 or less.

From the viewpoint of visibility of a light tone and suppression of a change in tint depending on a visual angle, the refractive index of the above-described layer B is preferably 1.5 or less, more preferably less than 1.5, still more preferably 1.4 or less, particularly preferably 1.35 or less, and most preferably 1.32 or less. In addition, the lower limit of the refractive index of the layer B is preferably 1.1 or more, more preferably 1.2 or more, and particularly preferably 1.28 or more.

The resin used for each layer such as the layer A and the layer B is not particularly limited, and examples thereof include an acrylic resin, a polycarbonate resin, a polyester resin, a polyolefin resin, an epoxy resin, a urethane resin, and a silicone resin.

The number of laminated layers in the organic multilayer film layer is not particularly limited as long as it is 2 or more, but is preferably 2 to 20, more preferably 4 to 16, and still more preferably 6 to 14.

From the viewpoint of visibility of a light tone and suppression of a change in tint depending on a visual angle, the thicknesses of the above-described layer A and the above-described layer B are each independently preferably 50 nm to 1,000 nm, more preferably 80 nm to 800 nm, still more preferably 100 nm to 500 nm, and particularly preferably 100 nm to 300 nm.

——Inorganic Multilayer Film Layer——

Suitable examples of the inorganic multilayer film layer include a layer having a structure in which two kinds of inorganic compounds are alternately laminated.

In addition, from the viewpoint of visibility of a light tone and suppression of a change in tint depending on a visual angle, the two kinds of inorganic compounds are preferably compounds having different refractive indices.

Examples of the inorganic compounds include silicon dioxide, aluminum oxide, gallium oxide, tungsten oxide, magnesium oxide, barium fluoride, calcium fluoride, cerium fluoride, lanthanum fluoride, lithium fluoride, sodium fluoride, magnesium fluoride, neodymium fluoride, ytterbium fluoride, yttrium fluoride, gadolinium fluoride, calcium carbonate, potassium bromide, titanium monoxide, titanium dioxide, niobium pentoxide, chromium oxide, cerium oxide, silicon, and gallium arsenide.

Among these, as the two kinds of inorganic compounds, from the viewpoint of visibility of a light tone and suppression of a change in tint depending on a visual angle, a combination of an inorganic oxide is preferable, a combination of niobium pentoxide (Nb₂O₅) or titanium dioxide (TiO₂) and silicon dioxide (SiO₂) or aluminum oxide (Al₂O₃) is more preferable, and a combination of niobium pentoxide and silicon dioxide is particularly preferable.

The number of laminated layers in the inorganic multilayer film layer is not particularly limited as long as it is 2 or more, but is preferably 2 to 20, more preferably 4 to 16, and still more preferably 6 to 14.

From the viewpoint of visibility of a light tone and suppression of a change in tint depending on a visual angle, the thickness of each layer in the inorganic multilayer film layer is independently preferably 50 nm to 1,000 nm, more preferably 80 nm to 800 nm, still more preferably 100 nm to 500 nm, and particularly preferably 100 nm to 300 nm.

——Cholesteric Liquid Crystal Layer——

In the present disclosure, the “cholesteric liquid crystal layer” is a layer having a molecular alignment state unique to a cholesteric liquid crystal. Hereinafter, the “alignment state of a molecule unique to a cholesteric liquid crystal” may be referred to as a “cholesteric alignment state” or simply an “alignment state”. The alignment state may include an alignment state in which dextrorotatory circularly polarized light is reflected, an alignment state in which levorotatory circularly polarized light is reflected, or both of these alignment states. The alignment state can be fixed by a method of polymerizing or crosslinking the cholesteric liquid crystal compound. The cholesteric liquid crystal layer may be a liquid crystal layer in which a cholesteric liquid crystal compound is fixed in a cholesteric alignment state.

In one embodiment, the cholesteric liquid crystal layer is a cured product of a liquid crystal composition containing a cholesteric liquid crystal compound.

### ———Cholesteric Liquid Crystal Compound———

The type of the cholesteric liquid crystal compound is not particularly limited, and a known compound in the related art can be used.

The cholesteric liquid crystal compound preferably has a reactive group. The reactive group is preferably a polymerizable group. Examples of the polymerizable group include a radically polymerizable group and a cationically polymerizable group. From the viewpoint of reactivity and ease of fixing a helical pitch, the cholesteric liquid crystal compound preferably has a radically polymerizable group. The radically polymerizable group is preferably at least one polymerizable group selected from the group consisting of a vinyl group, an acryloyl group, and a methacryloyl group, and more preferably at least one polymerizable group selected from the group consisting of an acryloyl group and a methacryloyl group.

The cholesteric liquid crystal compound may have two or more reactive groups. The cholesteric liquid crystal compound may have two or more types of reactive groups.

The cholesteric liquid crystal compound may be a cholesteric liquid crystal compound having two or more types of reactive groups having different crosslinking mechanisms. The crosslinking mechanism may be a condensation reaction, hydrogen bonding, or polymerization. It is preferable that at least one of the crosslinking mechanisms of the two or more types of reactive groups is polymerization. The crosslinking mechanism preferably includes two or more types of polymerizations. Examples of the reactive group used in the crosslinking mechanism as described above include a vinyl group, a (meth)acryloyl group, an epoxy group, an oxetanyl group, a vinyl ether group, a hydroxy group, a carboxy group, and an amino group.

The cholesteric liquid crystal compound having two or more types of reactive groups having different crosslinking mechanisms may be a compound that can be crosslinked in stages. At each stage, a reactive group corresponding to the crosslinking mechanism of each stage reacts.

Examples of a method for crosslinking two or more types of reactive groups in stages include a method of changing reaction conditions in each stage. Examples of the change point of the reaction conditions include a temperature, a wavelength of light (irradiation), and a polymerization mechanism. It is preferable to use a difference in polymerization mechanism from the viewpoint of easy separation of reactions. The polymerization mechanism is controlled by, for example, the type of the polymerization initiator.

The combination of polymerizable groups is preferably a combination of a radically polymerizable group and a cationically polymerizable group. From the viewpoint of easy control of reactivity, it is preferable that the radically polymerizable group is a vinyl group or a (meth)acryloyl group and the cationically polymerizable group is an epoxy group, an oxetanyl group, or a vinyl ether group as for the combination of polymerizable groups.

From the viewpoint of stretchability and heat resistance, the cholesteric liquid crystal compound preferably includes a cholesteric liquid crystal compound having one reactive group (preferably a polymerizable group). From the viewpoint of stretchability and heat resistance, the proportion of the content of the cholesteric liquid crystal compound having one reactive group with respect to the content of the cholesteric liquid crystal compound is preferably 96% by mass to 100% by mass, more preferably 97% by mass to 100% by mass, and still more preferably 98% by mass to 100% by mass.

From the viewpoint of stretchability and heat resistance, the cholesteric liquid crystal compound preferably includes a cholesteric liquid crystal compound having one reactive group and a cholesteric liquid crystal compound having two or more reactive groups. The cholesteric liquid crystal compound more preferably includes a cholesteric liquid crystal compound having one reactive group and a cholesteric liquid crystal compound having two reactive groups. From the viewpoint of stretchability and heat resistance, the ratio of the content of the cholesteric liquid crystal compound having two or more reactive groups to the content of the cholesteric liquid crystal compound having one reactive group is preferably 0 to 0.05, more preferably 0 to 0.04, and still more preferably 0 to 0.02, on a mass basis.

Specific examples of the reactive group are shown below. In this regard, the reactive group is not limited to the following specific examples. In the following specific examples, Et represents an ethyl group, and n-Pr represents an n-propyl group.

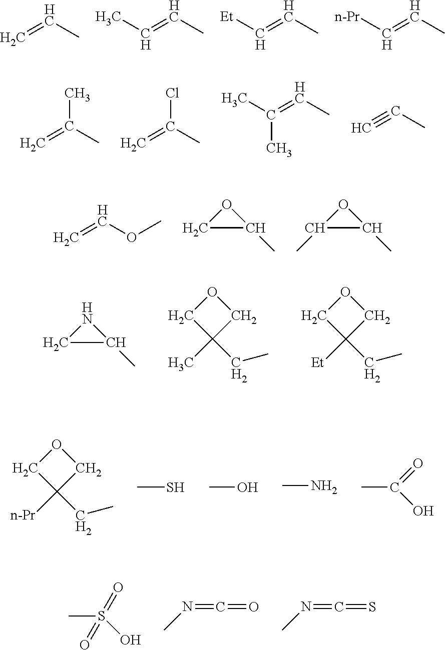

Examples of the cholesteric liquid crystal compound include a rod-like cholesteric liquid crystal compound and a disk-like cholesteric liquid crystal compound. The rod-like cholesteric liquid crystal compound may be a low-molecular-weight type compound or a high-molecular-weight type compound. The disk-like cholesteric liquid crystal compound may be a low-molecular-weight type compound or a high-molecular-weight type compound. In the present disclosure, the term “polymer” used for the cholesteric liquid crystal compound means a compound having a polymerization degree of 100 or more (Polymer Physics and Phase Transition Dynamics, written by Masao Doi, p. 2, Iwanami Shoten, Publishers, 1992). A mixture of two or more types of rod-like cholesteric liquid crystal compounds, a mixture of two or more types of disk-like liquid crystal compounds, or a mixture of a rod-like cholesteric liquid crystal compound and a disk-like cholesteric liquid crystal compound may be used. In two or more types of cholesteric liquid crystal compounds, it is preferable that at least one type of cholesteric liquid crystal compound has a reactive group.

The cholesteric liquid crystal compound is preferably a rod-like cholesteric liquid crystal compound. Examples of the rod-like cholesteric liquid crystal compound include azomethines, azoxys, cyano biphenyls, cyanophenyl esters, benzoic acid esters, cyclohexane carboxylic acid phenyl esters, cyanophenyl cyclohexanes, cyano-substituted phenyl pyrimidines, alkoxy-substituted phenyl pyrimidines, phenyl dioxanes, tolanes, and alkenylcyclohexylbenzonitriles. Examples of the rod-like cholesteric liquid crystal compound also include a polymer of a rod-like cholesteric liquid crystal compound having a reactive group. Examples of the rod-like cholesteric liquid crystal compound also include compounds described in JP2008-281989A, JP1999-513019A (JP-H11-513019A), and JP2006-526165A.

Specific examples of the rod-like cholesteric liquid crystal compound are shown below. In this regard, the rod-like cholesteric liquid crystal compound is not limited to the following specific examples. The compounds shown below are synthesized, for example, by the method described in JP1999-513019A (JP-H11-513019A).

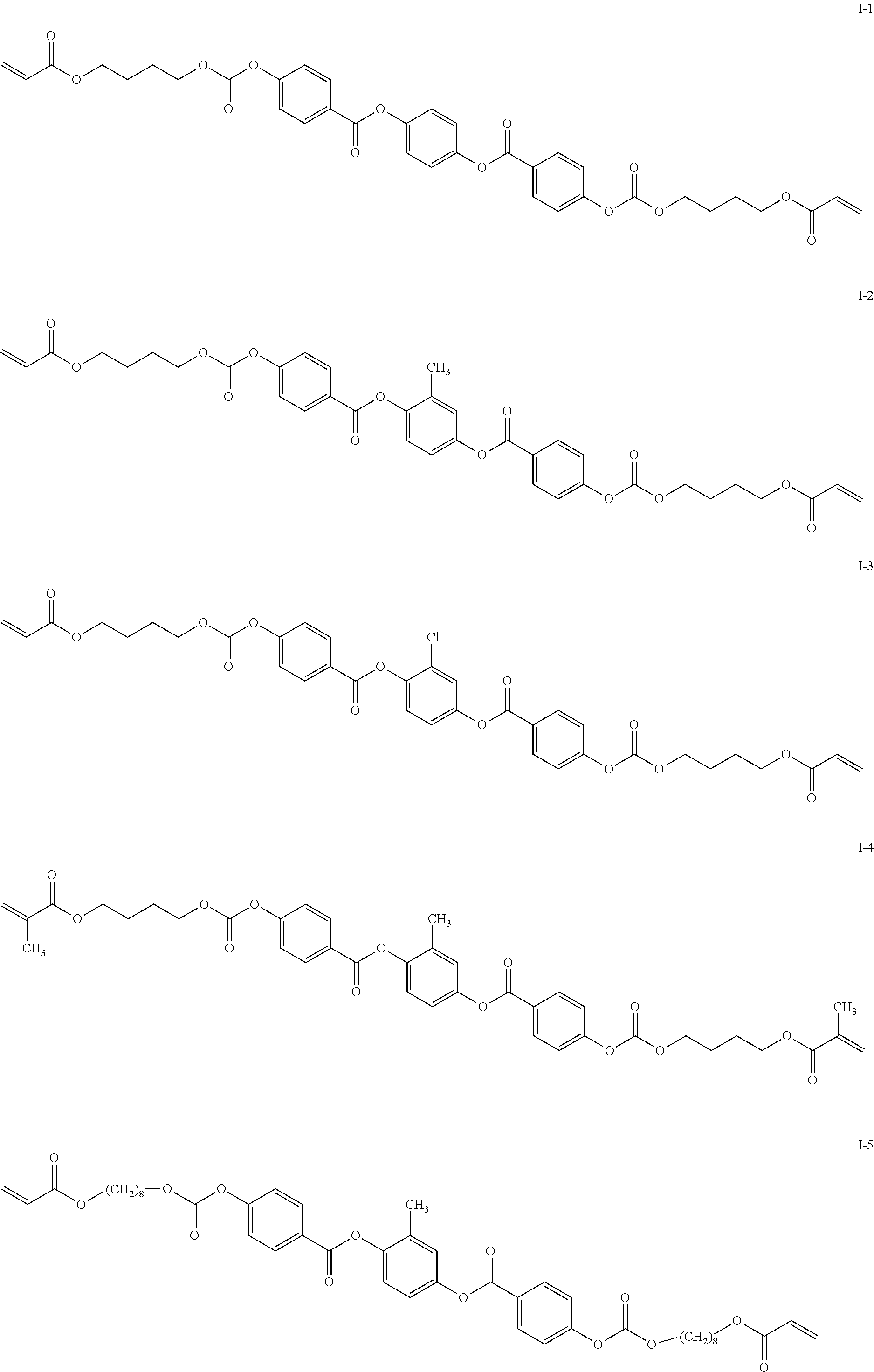

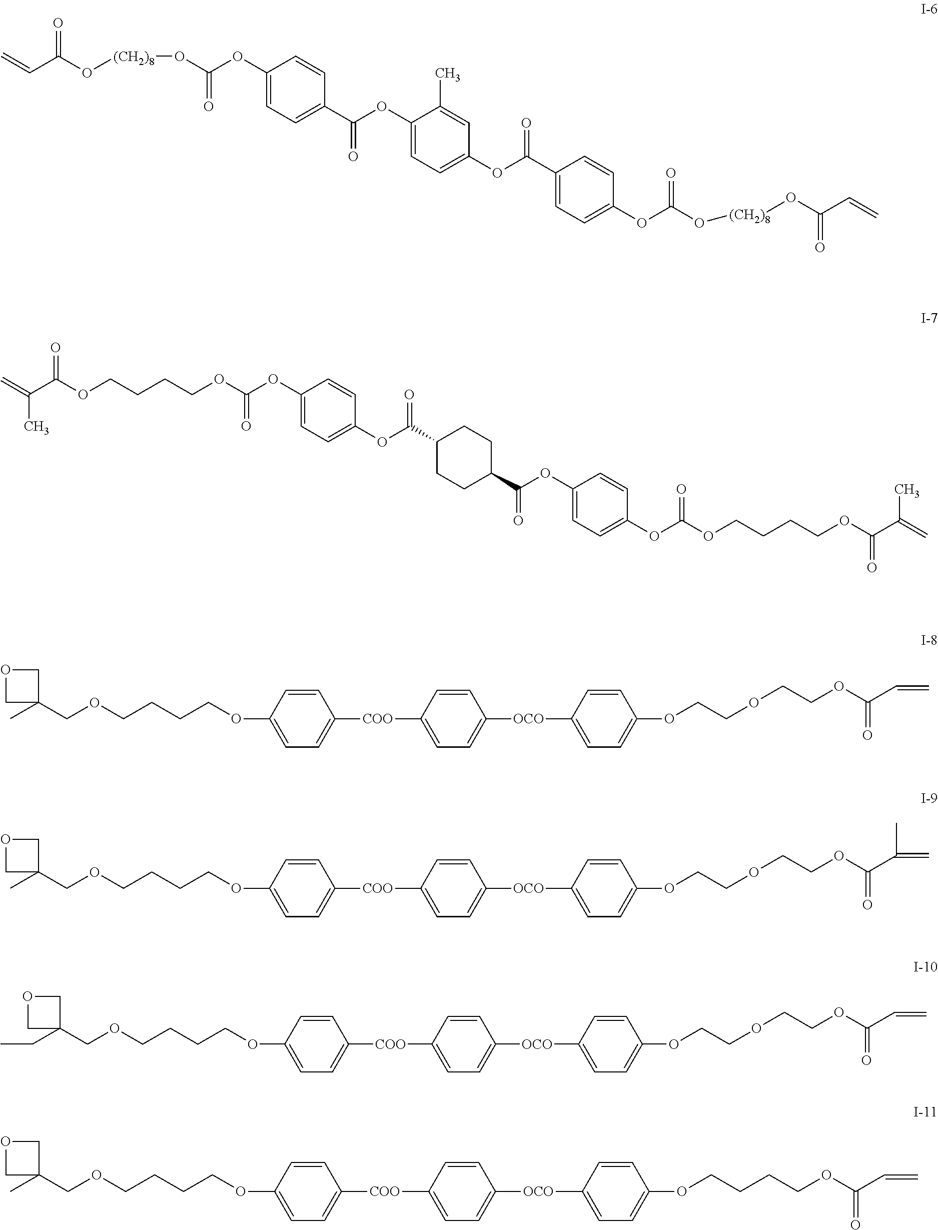

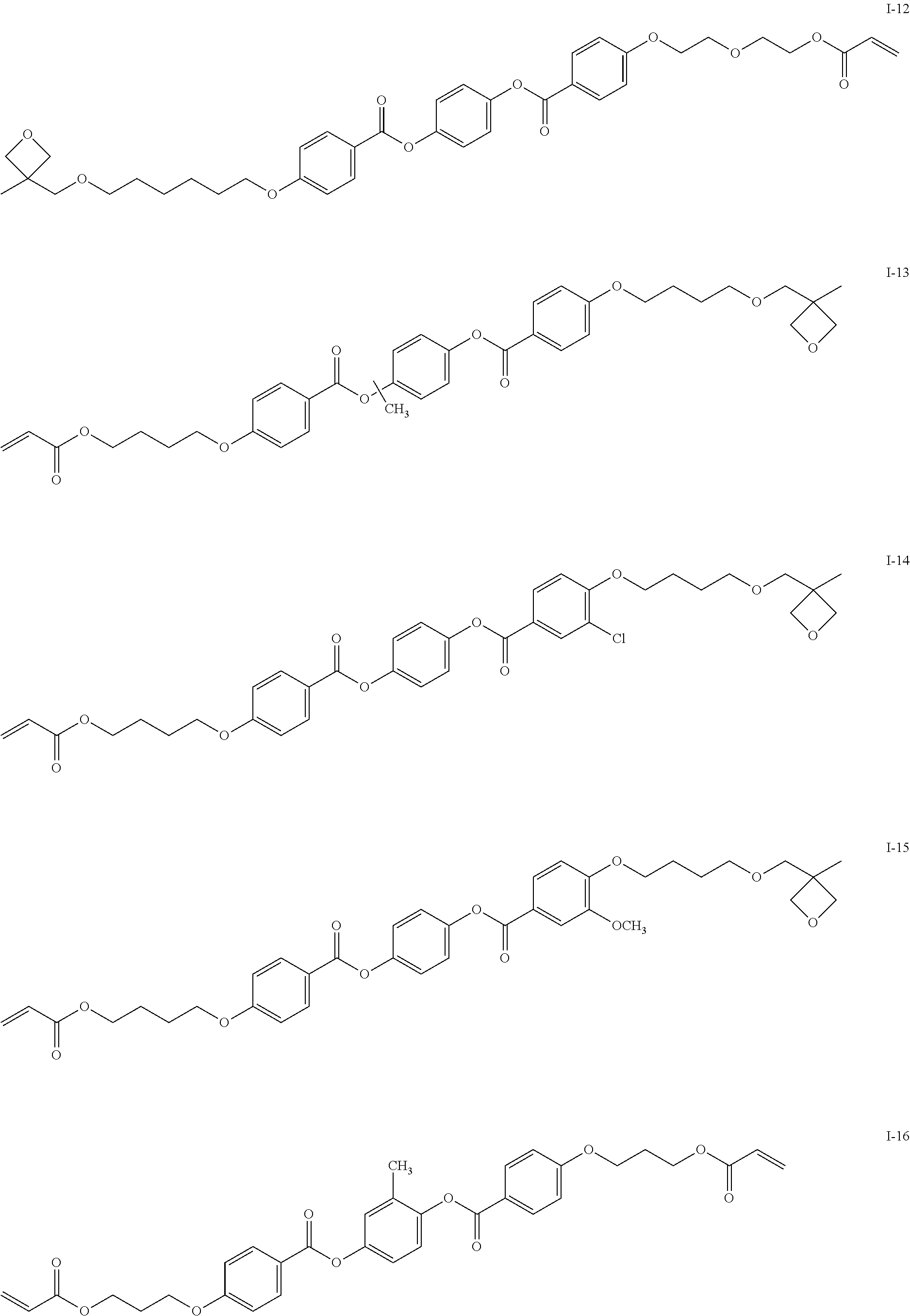

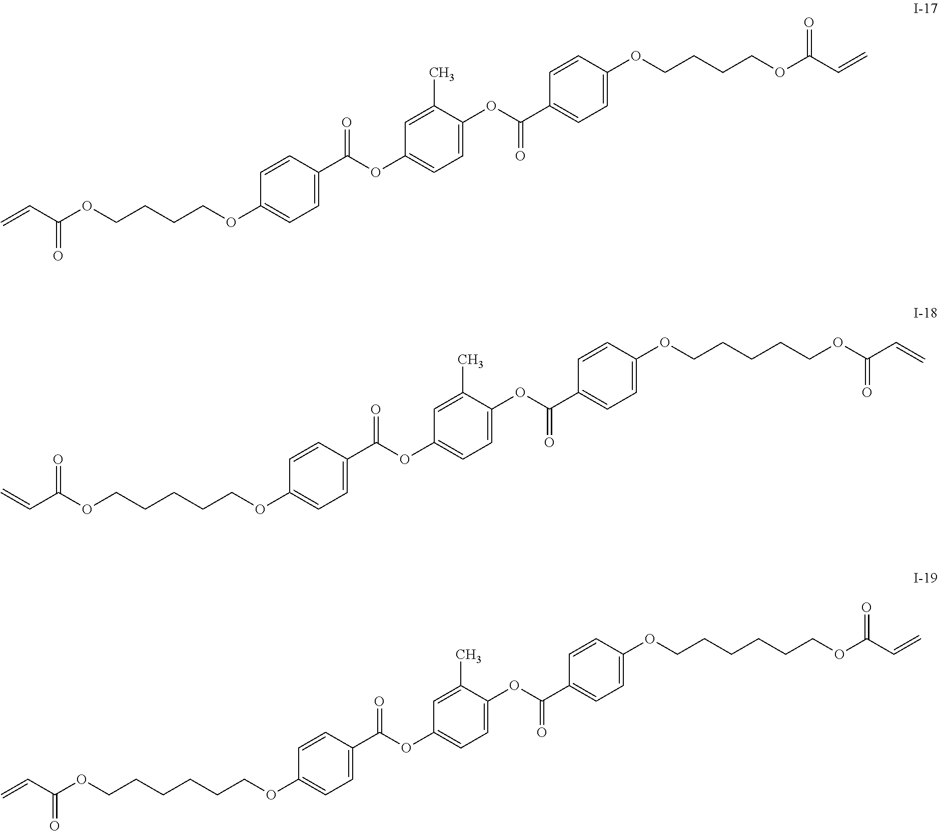

Examples of the rod-like cholesteric liquid crystal compound having one polymerizable group include the following compounds. “Me” in the following chemical formulae means a methyl group.

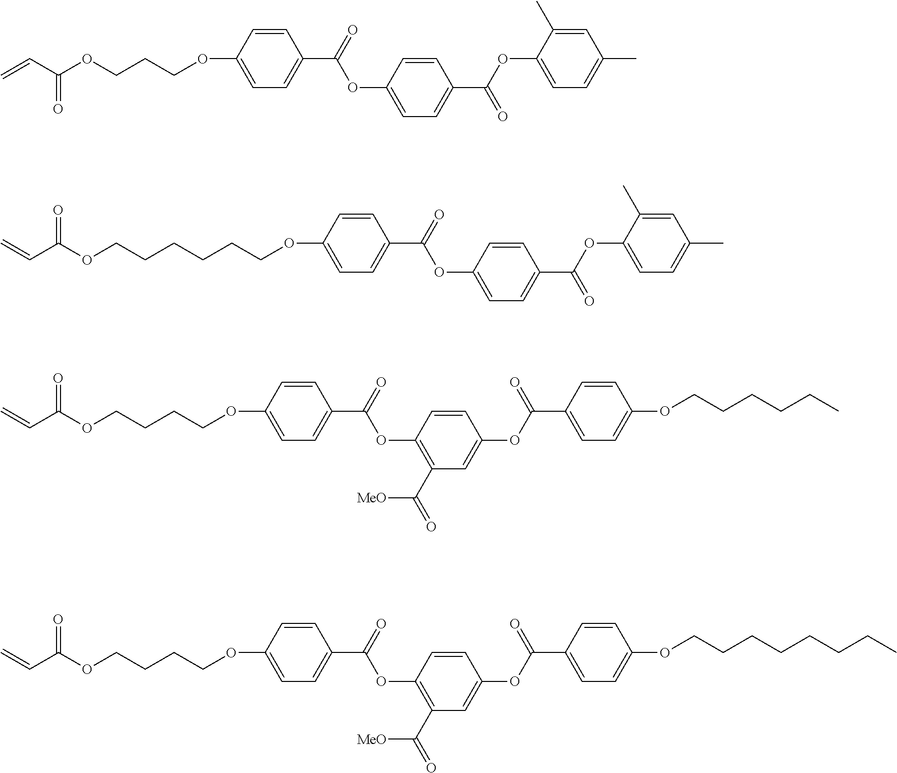

Examples of the disk-like cholesteric liquid crystal compound include the following compounds.
(1) Benzene derivatives described in a research report by C. Destrade et al., for example, Mol. Cryst. vol. 71, page 111 (1981)
(2) Truxene derivatives described in a research report by C. Destrade et al., for example, Mol. Cryst. vol. 122, p. 141 (1985) and Physics lett, A, vol. 78, p. 82 (1990)
(3) Cyclohexane derivatives described in a research report by B. Kohne et al., for example, Angew. Chem. vol. 96, p. 70 (1984)
(4) Azacrown-based or phenylacetylene-based macrocycles described in a research report by J. M. Lehn et al. (J. Chem. Commun., p. 1794 (1985)) and a research report by J. Zhang et al. (J. Am. Chem. Soc., vol. 116, p. 2655 (1994))

The disk-like cholesteric liquid crystal compound includes a liquid crystal compound, generally referred to as a disk-like liquid crystal, which has a structure in which the above-described various structures serve as a disk-like mother nucleus at the center of the molecule and groups such as a linear alkyl group, an alkoxy group, and a substituted benzoyloxy group are arranged in a radial manner, and which exhibits liquid crystallinity. In a case where an aggregate of such a compound is uniformly aligned, negative uniaxiality appears.

Examples of the disk-like cholesteric liquid crystal compound include the compounds described in paragraphs “0061” to “0075” of JP2008-281989A.

In the cholesteric liquid crystal layer, the disk-like cholesteric liquid crystal compound having a reactive group may be fixed in an alignment state such as horizontal alignment, vertical alignment, tilt alignment, or twisted alignment.

The liquid crystal composition may contain one type of cholesteric liquid crystal compound or two or more types of cholesteric liquid crystal compounds.

The proportion of the content of the cholesteric liquid crystal compound with respect to the total mass of the solid content of the liquid crystal composition is preferably 30% by mass to 99% by mass, more preferably 40% by mass to 99% by mass, still more preferably 60% by mass to 99% by mass, and particularly preferably 70% by mass to 98% by mass.

### ———Optically Active Compound (Chiral Agent)———

The liquid crystal composition preferably contains an optically active compound. The optically active compound can induce a helical structure of a cholesteric liquid crystal. For example, the helical pitch and a direction of the helix of the optically active compound can be adjusted.

The type of the optically active compound is not limited. The optically active compound may be a known optically active compound. The optically active compound may be selected depending on a desired helical structure. Examples of the optically active compound include the compounds described in Liquid Crystal Device Handbook (Chapter 3, Section 4-3, chiral agents for TN and STN, p. 199, edited by the 142nd Committee of Japan Society for the Promotion of Science, 1989), JP2003-287623A, JP2002-302487A, JP2002-80478A, JP2002-80851A, JP2010-181852A, and JP2014-034581A.

The optically active compound preferably has a cinnamoyl group.

The optically active compound preferably contains an asymmetric carbon atom. In this regard, the optically active compound may be an axially chiral compound or planar chiral compound which does not contain an asymmetric carbon atom. Examples of the axially chiral compound and the planar chiral compound include binaphthyl, helicene, paracyclophane, and derivatives thereof.

The optically active compound may have a reactive group. The reactive group is preferably a polymerizable group. The polymerizable group is preferably at least one polymerizable group selected from the group consisting of an ethylenically unsaturated group, an epoxy group, and an aziridinyl group, more preferably an ethylenically unsaturated group, and still more preferably at least one polymerizable group selected from the group consisting of an acryloyl group and a methacryloyl group. The optically active compound may have two or more reactive groups. The optically active compound may have two or more types of reactive groups.

From the viewpoint of stretchability and heat resistance, the optically active compound preferably includes an optically active compound having one polymerizable group. In a case where the optically active compound includes an optically active compound having one polymerizable group, the proportion of the content of the optically active compound having one polymerizable group with respect to the content of the optically active compound is preferably more than 0% by mass, more preferably 50% by mass or more, and still more preferably 70% by mass or more, from the viewpoint of stretchability and heat resistance. The upper limit of the proportion of the content of the optically active compound having one polymerizable group may be 100% by mass. The proportion of the content of the optically active compound having one polymerizable group with respect to the content of the optically active compound may be 0% by mass to 100% by mass.

The liquid crystal composition preferably contains a cholesteric liquid crystal compound having a polymerizable group and an optically active compound having a polymerizable group. For example, the reaction between the optically active compound having a polymerizable group and the cholesteric liquid crystal compound having a polymerizable group can form a polymer having a constitutional unit derived from the cholesteric liquid crystal compound having a polymerizable group and a constitutional unit derived from the optically active compound having a polymerizable group. It is preferable that the type of the polymerizable group in the optically active compound is the same as the type of the polymerizable group in the cholesteric liquid crystal compound.

The optically active compound may be a cholesteric liquid crystal compound.

From the viewpoint of ease of forming a liquid crystal layer, ease of adjusting a helical pitch, and suppression of change in reflectivity, the optically active compound may be a photoisomerization compound (photosensitive chiral agent) that also acts as an optically active compound. Examples of the photoisomerization compound that also acts as the optically active compound include a compound represented by Formula (CH1) which will be described later.

Preferred examples of the optically active compound include an isosorbide derivative, an isomannide derivative, and a binaphthyl derivative.

Specific examples of the optically active compound are shown below. In this regard, the optically active compound is not limited to the following specific examples.

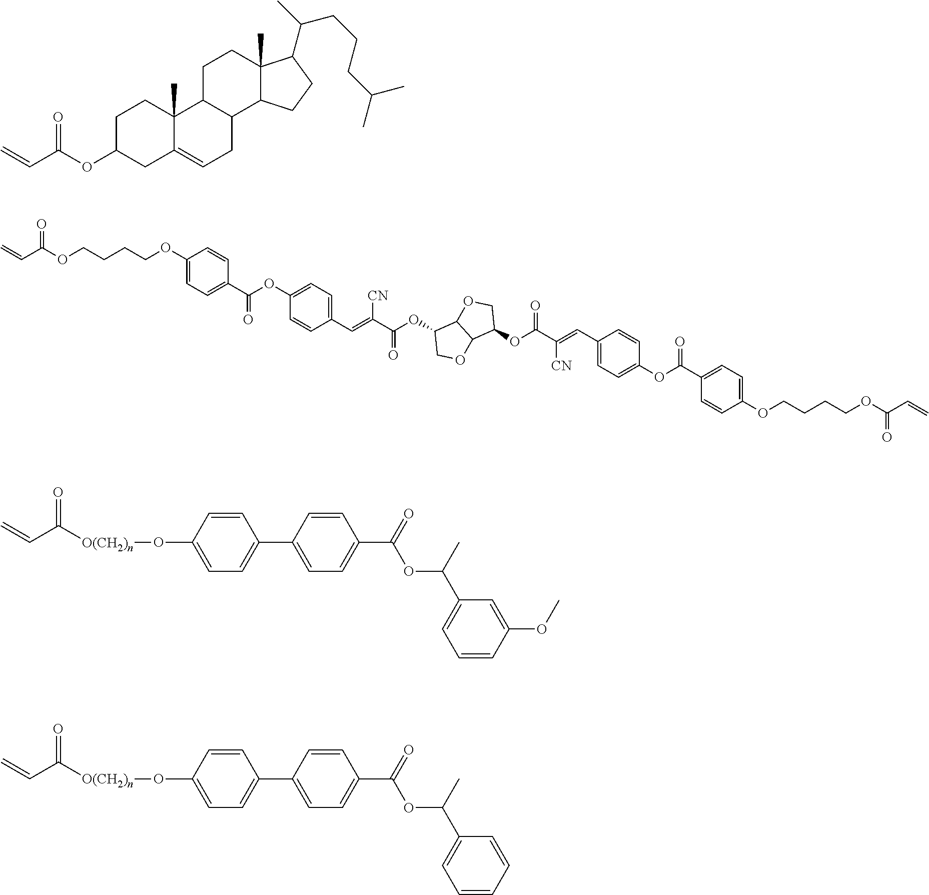

In the above chemical formulae, n represents an integer of 2 to 12. From the viewpoint of synthesis cost, n is preferably 2 or 4.

The liquid crystal composition may contain one type of optically active compound or two or more types of optically active compounds.

From the viewpoint of ease of forming the cholesteric liquid crystal layer, ease of adjusting the helical pitch, and suppression of change in reflectivity, a proportion of a content of the optically active compound to the total mass of the solid content of the liquid crystal composition is preferably 1% by mass to 20% by mass, more preferably 2% by mass to 10% by mass, still more preferably 3% by mass to 9% by mass, and particularly preferably 4% by mass to 8% by mass.

From the viewpoint of suppression of change in reflectivity, the proportion of the content of the optically active compound having a polymerizable group with respect to the total mass of the solid content of the liquid crystal composition is preferably 0.2% by mass to 15% by mass, more preferably 0.5% by mass to 10% by mass, still more preferably 1% by mass to 8% by mass, and particularly preferably 1.5% by mass to 5% by mass.

From the viewpoint of suppression of change in reflectivity, the proportion of the content of the optically active compound having no polymerizable group with respect to the total mass of the solid content of the liquid crystal composition is preferably 0.2% by mass to 20% by mass, more preferably 0.5% by mass to 10% by mass, and particularly preferably 2% by mass to 8% by mass.

The helical pitch, and the selective reflection wavelength and the range thereof which will be described later are adjusted, for example, depending on not only the type of the cholesteric liquid crystal compound but also the content of the optically active compound. For example, in a case where the content of the optically active compound in the cholesteric liquid crystal layer is doubled, the helical pitch is ½, and the center value of the selective reflection wavelength is also ½.

### ———Polymerization Initiator———

It is preferable that the liquid crystal composition contains a polymerization initiator.

The type of the polymerization initiator is not limited. The polymerization initiator may be a known polymerization initiator. The polymerization initiator is preferably a photopolymerization initiator. Examples of the photopolymerization initiator include an α-carbonyl compound (see, for example, U.S. Pat. Nos. 2,367,661A and 2,367,670A), an acyloin ether compound (see, for example, U.S. Pat. No. 2,448,828A), an α-hydrocarbon-substituted aromatic acyloin compound (see, for example, U.S. Pat. No. 2,722,512A), a polynuclear quinone compound (see, for example, U.S. Pat. Nos. 3,046,127A and 2,951,758A), a combination of a triarylimidazole dimer and p-aminophenyl ketone (see, for example, U.S. Pat. No. 3,549,367A), an acridine compound and a phenazine compound (see, for example, JP1985-105667A (JP-S60-105667A) and U.S. Pat. No. 4,239,850A), and an oxadiazole compound (see, for example, U.S. Pat. No. 4,212,970A).

Examples of the photopolymerization initiator include a photoradical polymerization initiator and a photocationic polymerization initiator. Preferred examples of the photoradical polymerization initiator include an α-hydroxyalkylphenone compound, an α-aminoalkylphenone compound, an acylphosphine oxide compound, a thioxanthone compound, and an oxime ester compound. Preferred examples of the photocationic polymerization initiator include an iodonium salt compound and a sulfonium salt compound.

The liquid crystal composition may contain one type of polymerization initiator or two or more types of polymerization initiators.

From the viewpoint of ease of adjusting a helical pitch, a polymerization rate, and the strength of a cholesteric liquid crystal layer after curing, the proportion of the content of the polymerization initiator with respect to the total mass of the solid content of the liquid crystal composition is preferably 0.05% by mass to 10% by mass, more preferably 0.05% by mass to 5% by mass, still more preferably 0.1% by mass to 4% by mass, and particularly preferably 0.2% by mass to 3% by mass.

### ———Polymerizable Monomer———

The liquid crystal composition may contain a polymerizable monomer. The polymerizable monomer can promote crosslinking of the cholesteric liquid crystal compound.

Examples of the polymerizable monomer include a monomer or oligomer that has two or more ethylenically unsaturated bonds and undergoes addition polymerization upon irradiation with light.

Examples of the polymerizable monomer include a compound having an addition-polymerizable ethylenically unsaturated group.

Examples of the polymerizable monomer include a monofunctional acrylate, a monofunctional methacrylate, a polyfunctional acrylate, and a polyfunctional methacrylate.

Examples of the polymerizable monomer include polyethylene glycol mono(meth)acrylate, polypropylene glycol mono(meth)acrylate, and phenoxyethyl (meth)acrylate.

Examples of the polymerizable monomer include polyethylene glycol di(meth)acrylate, polypropylene glycol di(meth)acrylate, trimethylolethane triacrylate, trimethylolpropane tri(meth)acrylate, trimethylolpropane diacrylate, cyclohexane dimethanol acrylate, neopentyl glycol di(meth)acrylate, pentaerythritol tetra(meth)acrylate, pentaerythritol tri(meth)acrylate, dipentaerythritol hexa(meth)acrylate, dipentaerythritol penta(meth)acrylate, hexanediol di(meth)acrylate, trimethylolpropane tri(acryloyloxypropyl)ether, tri(acryloyloxyethyl) isocyanurate, tri(acryloyloxyethyl) cyanurate, tricyclodecane dimethanol dimethacrylate, and glycerin tri(meth)acrylate.

Examples of the polymerizable monomer include a compound formed by adding ethylene oxide or propylene oxide to a polyfunctional alcohol such as trimethylolpropane or glycerin, followed by (meth)acrylation.

Examples of the polymerizable monomer include urethane acrylates described in JP1973-41708B (JP-S48-41708B), JP1975-6034B (JP-S50-6034B), and JP1976-37193A (JP-S51-37193A).

Examples of the polymerizable monomer include polyester acrylates described in JP1973-64183A (JP-S48-64183A), JP1974-43191B (JP-S49-43191B), and JP1977-30490B (JP-S52-30490B).

Examples of the polymerizable monomer include epoxy acrylates, which are reaction products of an epoxy resin and a (meth)acrylic acid.

Preferred examples of the polymerizable monomer include trimethylolpropane tri(meth)acrylate, pentaerythritol tetra(meth)acrylate, dipentaerythritol hexa(meth)acrylate, and dipentaerythritol penta(meth)acrylate.

Preferred examples of the polymerizable monomer include the “polymerizable compound B” described in JP1999-133600A (JP-H11-133600A).

The polymerizable monomer may be a cationically polymerizable monomer. Examples of the cationically polymerizable monomer include an epoxy compound, a vinyl ether compound, and an oxetane compounds described in JP1994-9714A (JP-H6-9714A), JP2001-31892A, JP2001-40068A, JP2001-55507A, JP2001-310938A, JP2001-310937A, and JP2001-220526A.

Examples of the epoxy compound include an aromatic epoxide, an alicyclic epoxide, and an aliphatic epoxide.

Examples of the aromatic epoxide include a diglycidyl ether or polyglycidyl ether of bisphenol A, a diglycidyl ether or polyglycidyl ether of an alkylene oxide adduct of bisphenol A, a diglycidyl ether or polyglycidyl ether of hydrogenated bisphenol A, a diglycidyl ether or polyglycidyl ether of an alkylene oxide adduct of hydrogenated bisphenol A, and a novolac type epoxy resin. Examples of the alkylene oxide include ethylene oxide and propylene oxide.

Examples of the alicyclic epoxide include a cyclohexene oxide-containing compound or cyclopentene oxide-containing compound which is obtained by epoxidizing a compound having a cycloalkane ring (for example, a cyclohexene ring or a cyclopentene ring) with an oxidizing agent (for example, hydrogen peroxide or peracid).

Examples of the aliphatic epoxide include a diglycidyl ether or polyglycidyl ether of an aliphatic polyhydric alcohol and a diglycidyl ether or polyglycidyl ether of an alkylene oxide adduct of an aliphatic polyhydric alcohol. Examples of the aliphatic epoxide include a diglycidyl ether of alkylene glycol (for example, a diglycidyl ether of ethylene glycol, a diglycidyl ether of propylene glycol, or a diglycidyl ether of 1,6-hexanediol). Examples of the aliphatic epoxide include a polyglycidyl ether of a polyhydric alcohol (for example, a diglycidyl ether or polyglycidyl ether of glycerin or a diglycidyl ether or polyglycidyl ether of an alkylene oxide adduct of glycerin). Examples of the aliphatic epoxide include a diglycidyl ether of a polyalkylene glycol (for example, a diglycidyl ether of polyethylene glycol or a diglycidyl ether of an alkylene oxide adduct of polyethylene glycol or a diglycidyl ether of polypropylene glycol or a diglycidyl ether of an alkylene oxide adduct of polypropylene glycol). Examples of the alkylene oxide include ethylene oxide and propylene oxide.

Examples of the cationically polymerizable monomer include a monofunctional or difunctional oxetane monomer. For example, 3-ethyl-3-hydroxymethyl-oxetane (for example, OXT-101 manufactured by Toagosei Co., Ltd.), 1,4-bis[(3-ethyl-3-oxetanyl)methoxymethyl]benzene (for example, OXT-121 manufactured by Toagosei Co., Ltd.), 3-ethyl-3-(phenoxymethyl)oxetane (for example, OXT-211 manufactured by Toagosei Co., Ltd.), di(1-ethyl-3-oxetanyl)methylether (for example, OXT-221 manufactured by Toagosei Co., Ltd.), 3-ethyl-3-(2-ethylhexyloxymethyl)oxetane (for example, OXT-212 manufactured by Toagosei Co., Ltd.), and the like are preferably used. In particular, 3-ethyl-3-hydroxymethyloxetane, 3-ethyl-3-(phenoxymethyl)oxetane, or di(1-ethyl-3-oxetanyl)methyl ether are preferable. The monofunctional or polyfunctional oxetane compounds described in JP2001-220526A and JP2001-310937A may be used.

### ———Polyfunctional Polymerizable Compound———

The liquid crystal composition may contain a polyfunctional polymerizable compound.

Examples of the polyfunctional polymerizable compound include a cholesteric liquid crystal compound having two or more ethylenically unsaturated groups and not having a cyclic ether group, a cholesteric liquid crystal compound having two or more cyclic ether groups and not having an ethylenically unsaturated group, a cholesteric liquid crystal compound having two or more ethylenically unsaturated groups and two or more cyclic ether groups, an optically active compound having two or more polymerizable groups, and a crosslinking agent.

Preferred examples of the ethylenically unsaturated group include a (meth)acryloyl group. More preferred examples of the ethylenically unsaturated group include a (meth)acryloxy group.

Preferred examples of the cyclic ether group include an epoxy group and an oxetanyl group. More preferred examples of the cyclic ether group include an oxetanyl group.

The polyfunctional polymerizable compound preferably includes at least one compound selected from the group consisting of a cholesteric liquid crystal compound having two or more ethylenically unsaturated groups and not having a cyclic ether group, a cholesteric liquid crystal compound having two or more cyclic ether groups and not having an ethylenically unsaturated group, and an optically active compound having two or more polymerizable groups, and more preferably includes an optically active compound having two or more polymerizable groups.

The liquid crystal composition may contain one type of polyfunctional polymerizable compound or two or more types of polyfunctional polymerizable compounds.

From the viewpoint of suppression of change in reflectivity, the proportion of the content of the polyfunctional polymerizable compound with respect to the total mass of the solid content of the liquid crystal composition is preferably 0.5% by mass to 70% by mass, more preferably 1% by mass to 50% by mass, still more preferably 1.5% by mass to 20% by mass, and particularly preferably 2% by mass to 10% by mass.

### ———Photoisomerization Compound———

The liquid crystal composition may contain a photoisomerization compound.

The type of the photoisomerization compound is not limited. The photoisomerization compound may be any known photoisomerization compound. From the viewpoint of suppression of change in reflectivity and maintenance of an isomerization structure, a compound in which a three-dimensional structure changes by exposure is preferable.

The photoisomerization compound has a photoisomerization structure. From the viewpoint of suppression of change in reflectivity, ease of photoisomerization, and maintenance of an isomerization structure, the photoisomerization compound preferably has a structure in which a three-dimensional structure changes by exposure, more preferably has a di- or higher substituted ethylenically unsaturated bond in which an EZ configuration is isomerized by exposure, and particularly preferably has a di-substituted ethylenically unsaturated bond in which an EZ configuration is isomerized by exposure. The isomerization of the EZ configuration includes cis-trans isomerization. The di-substituted ethylenically unsaturated bond is preferably an ethylenically unsaturated bond substituted with an aromatic group and an ester bond.

In the present disclosure, unless otherwise specified, “exposure” includes not only exposure by a bright line spectrum of a mercury lamp, far ultraviolet rays typified by excimer lasers, extreme ultraviolet rays, X-rays, EUV light, or the like, but also exposure by corpuscular beams such as electron beams and ion beams.

From the viewpoint of suppression of change in reflectivity, ease of photoisomerization, and maintenance of an isomerization structure, the photoisomerization compound preferably has 2 or more photoisomerization structures. The number of photoisomerization structures in the photoisomerization compound is preferably 2 to 4 and more preferably 2.

The photoisomerization compound is preferably a photoisomerization compound that also acts as the above-mentioned optically active compound. The photoisomerization compound that also acts as an optically active compound is preferably an optically active compound having a molar absorption coefficient of 30,000 or more at a wavelength of 313 nm.

Examples of the photoisomerization compound that also acts as the optically active compound include a compound represented by Formula (CH1) which will be described later. The compound represented by Formula (CH1) can change an alignment structure such as a helical pitch (twisting force and helical twisting angle) depending on an amount of light at the time of irradiation with light. In addition, the compound represented by Formula (CH1) is a compound in which an EZ configuration in two ethylenically unsaturated bonds can be isomerized by exposure.

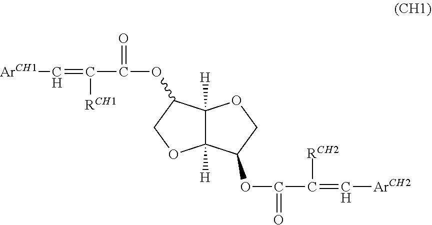

In Formula (CH1), Ar^{CH1} and Ar^{CH2} each independently represent an aryl group or a heteroaromatic ring group, and R^{CH1} and R^{CH2} each independently represent a hydrogen atom or a cyano group.

In Formula (CH1), it is preferable that Ar^{CH1} and Ar^{CH2} are each independently an aryl group. The aryl group may have a substituent. The substituent is preferably, for example, a halogen atom, an alkyl group, an alkenyl group, an alkynyl group, an alkoxy group, a hydroxy group, an acyl group, an alkoxycarbonyl group, an aryloxycarbonyl group, an acyloxy group, a carboxy group, a cyano group, or a heterocyclic group, and more preferably a halogen atom, an alkyl group, an alkenyl group, an alkoxy group, a hydroxy group, an acyloxy group, an alkoxycarbonyl group, or an aryloxycarbonyl group. The total number of carbon atoms in the aryl group is preferably 6 to 40 and more preferably 6 to 30.

It is preferable that Ar^{CH1} and Ar^{CH2} are each independently an aryl group represented by Formula (CH2) or Formula (CH3).

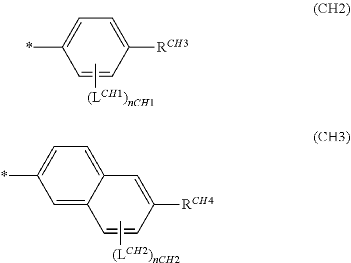

In Formula (CH2) and Formula (CH3), R^{CH3} and R^{CH4} each independently represent a hydrogen atom, a halogen atom, an alkyl group, an alkenyl group, an alkynyl group, an aryl group, a heterocyclic group, an alkoxy group, a hydroxy group, an acyl group, an alkoxycarbonyl group, an aryloxycarbonyl group, an acyloxy group, a carboxy group, or a cyano group, L^{CH1} and L^{CH2} each independently represent a halogen atom, an alkyl group, an alkoxy group, or a hydroxy group, nCH1 represents an integer of 0 to 4, nCH2 represents an integer of 0 to 6, and * represents a bonding position with the ethylenically unsaturated bond in Formula (CH1).

In Formula (CH2) and Formula (CH3), R^{CH3} and R^{CH4} are each independently preferably a hydrogen atom, a halogen atom, an alkyl group, an alkenyl group, an aryl group, an alkoxy group, a hydroxy group, an alkoxycarbonyl group, an aryloxycarbonyl group, or an acyloxy group, more preferably an alkoxy group, a hydroxy group, or an acyloxy group, and particularly preferably an alkoxy group.

In Formula (CH2) and Formula (CH3), L^{CH1} and L^{CH2} are each independently preferably an alkoxy group having 1 to 10 carbon atoms, or a hydroxy group.

nCH1 in Formula (CH2) is preferably 0 or 1.

nCH2 in Formula (CH3) is preferably 0 or 1.

The heteroaromatic ring group in Ar^{CH1} and Ar^{CH2} in Formula (CH1) may have a substituent. The substituent is preferably, for example, a halogen atom, an alkyl group, an alkenyl group, an alkynyl group, an aryl group, an alkoxy group, a hydroxy group, an acyl group, an alkoxycarbonyl group, an aryloxycarbonyl group, an acyloxy group, or a cyano group, and more preferably a halogen atom, an alkyl group, an alkenyl group, an aryl group, an alkoxy group, or an acyloxy group. The total number of carbon atoms in the heteroaromatic ring group is preferably 4 to 40 and more preferably 4 to 30. The heteroaromatic ring group is preferably a pyridyl group, a pyrimidinyl group, a furyl group, or a benzofuranyl group, and more preferably a pyridyl group or a pyrimidinyl group.

In Formula (CH1), it is preferable that R^{CH1} and R^{CH2} are each independently a hydrogen atom.

Preferred specific examples of the photoisomerization compound are shown below. In the following specific examples, Bu represents an n-butyl group. In the following compounds, the steric configuration of each ethylenically unsaturated bond is an E-form (trans-form), which changes to Z-form (cis-form) by exposure.

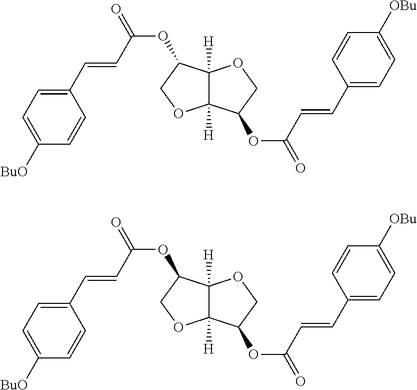

The liquid crystal composition may contain one type of photoisomerization compound or two or more types of photoisomerization compounds.

From the viewpoint of suppression of change in reflectivity, the proportion of the content of the photoisomerization compound with respect to the total mass of the solid content of the liquid crystal composition is preferably 1% by mass to 20% by mass, more preferably 2% by mass to 10% by mass, still more preferably 3% by mass to 9% by mass, and particularly preferably 4% by mass to 8% by mass.

### ———Crosslinking Agent———

The liquid crystal composition may include a crosslinking agent. The crosslinking agent can improve the strength and durability of the cholesteric liquid crystal layer after curing.

The type of the crosslinking agent is not limited. The crosslinking agent may be a known crosslinking agent. The crosslinking agent is preferably a compound which is cured by ultraviolet rays, heat, or moisture.

Examples of the crosslinking agent include polyfunctional acrylate compounds such as trimethylolpropane tri(meth)acrylate and pentaerythritol tri(meth)acrylate; epoxy compounds such as glycidyl (meth)acrylate, ethylene glycol diglycidyl ether, and 3′,4′-epoxycyclohexylmethyl 3,4-epoxycyclohexanecarboxylate; oxetane compounds such as 2-ethylhexyloxetane and xylylenebisoxetane; aziridine compounds such as 2,2-bishydroxymethylbutanol-tris[3-(1-aziridinyl)propionate] and 4,4-bis(ethyleneiminocarbonylamino)diphenylmethane; isocyanate compounds such as hexamethylene diisocyanate and biuret-type isocyanate; polyoxazoline compounds having an oxazoline group in the side chain; and alkoxysilane compounds such as vinyltrimethoxysilane and N-(2-aminoethyl) 3-aminopropyltrimethoxysilane. In addition, a known catalyst may be used depending on the reactivity of the crosslinking agent. The use of the catalyst can improve productivity in addition to improving the strength and durability of the liquid crystal layer.

The liquid crystal composition may contain one type of crosslinking agent or two or more types of crosslinking agents.

From the viewpoint of strength and durability of the cholesteric liquid crystal layer, the proportion of the content of the crosslinking agent with respect to the total mass of the solid content of the liquid crystal composition is preferably 1% by mass to 20% by mass, and more preferably 3% by mass to 15% by mass.

### ———Solvent———

The liquid crystal composition may include a solvent.

Examples of the solvent include an organic solvent. Examples of the organic solvent include a ketone compound (for example, methyl ethyl ketone and methyl isobutyl ketone), an alkyl halide compound, an amide compound, a sulfoxide compound, a heterocyclic compound, a hydrocarbon compound, an ester compound, an ether compound, and an alcohol compound. A ketone compound is preferable in consideration of the burden on the environment.

Examples of the solvent include a high boiling point solvent. In a case where the composition contains a high boiling point solvent, the viscosity of the liquid crystal during drying decreases, and the aligning properties of the liquid crystal are improved. The boiling point of the high boiling point solvent is preferably 150° C. or higher and more preferably 160° C. or higher. Examples of the high boiling point solvent include furfuryl alcohol, 2-thiophenemethanol, benzyl alcohol, tetrahydrofurfuryl alcohol, γ-butyrolactone, N-methyl-2-pyrrolidone, ethyl acetoacetate, methyl benzoate, ethyl benzoate, and methyl o-toluate.

The liquid crystal composition may contain one type of solvent or two or more types of solvents.

The proportion of the content of the solvent with respect to the total mass of the liquid crystal composition is preferably 50% by mass to 85% by mass, more preferably 60% by mass to 80% by mass, and still more preferably 65% by mass to 75% by mass. From the viewpoint of the aligning properties of the liquid crystal, the proportion of the content of the high boiling point solvent with respect to the content of the solvent is preferably 2% by mass to 30% by mass, more preferably 4% by mass to 25% by mass, and still more preferably 6% by mass to 20% by mass.

### ———Other Additives———

The liquid crystal composition may include other additives. Examples of the other additives include a surfactant, a polymerization inhibitor, an antioxidant, a horizontal alignment agent, an ultraviolet absorber, a light stabilizer, a colorant, and metal oxide particles.

### (Method for Forming Specific Layer)

In one embodiment, the specific layer can be formed by applying the liquid crystal composition onto a support or an undercoat layer and curing the liquid crystal composition.

In addition, after the application of the liquid crystal composition and before the curing, by isomerizing the photoisomerization compound, it is possible to form the specific layer having a plurality of regions having different maximum peak wavelengths of reflectivity in a plane.

The liquid crystal composition may be applied by a roll coating method, a gravure printing method, or a spin coating method. The liquid crystal composition may be applied by a wire bar coating method, an extrusion coating method, a direct gravure coating method, a reverse gravure coating method, or a die-coating method. The liquid crystal composition may be applied using an ink jet device. In the coating method using an ink jet device, the liquid crystal composition may be jetted from a nozzle.

The liquid crystal composition applied onto the support or the undercoat layer may be dried by a known method. The liquid crystal composition may be dried by being left to stand. The liquid crystal composition may be dried by air drying. The liquid crystal composition may be dried by heating. In the liquid crystal composition that has been subjected to the application and the drying, it is preferable that the cholesteric liquid crystal compound is aligned.

The liquid crystal composition can be cured by irradiating the liquid crystal composition with light.

It is preferable that the wavelength of the irradiated light is appropriately changed depending on an absorption wavelength of the photopolymerization initiator and the like contained in the liquid crystal composition.

It is preferable that the light emitted to the liquid crystal composition is light including a wavelength in an ultraviolet range of 300 nm or less.

The adjustment of the wavelength of light may be carried out by a known means and a known method. Examples of a method of adjusting the wavelength of light include a method of using an optical filter, a method of using two or more types of optical filters, and a method of using a light source having a specific wavelength.

The exposure amount is not particularly limited, and is preferably 5 mJ/cm² to 2,000 mJ/cm² and more preferably 10 mJ/cm² to 1,000 mJ/cm².

The emitted light is not particularly limited, but ultraviolet rays are preferable.

Examples of the light source include an ultra-high pressure mercury lamp, a high pressure mercury lamp, and a metal halide lamp. In addition, examples of the light source also include a light emitting diode capable of emitting light in a narrow wavelength range.

The curing of the liquid crystal composition may include curing the liquid crystal composition with light under heating conditions. The cholesteric liquid crystal compound can be easily arranged by curing under heating conditions. A heating temperature may be determined according to the composition of the liquid crystal composition. The heating temperature may be 30° C. to 120° C.

The oxygen concentration in the curing is not limited. The curing may be carried out in an oxygen atmosphere. The curing may be carried out in an atmosphere. The curing may be carried out under a low oxygen atmosphere (preferably at an oxygen concentration of 1,000 ppm or less). The oxygen concentration may be 0 ppm. The oxygen concentration may be more than 0 ppm and 1,000 ppm or less. From the viewpoint of accelerating curing, the curing is preferably carried out under a low oxygen atmosphere, and more preferably carried out under heating and under a low oxygen atmosphere.

The isomerization of the photoisomerization compound can be performed by subjecting the liquid crystal composition after applying and before curing to an isomerization treatment.

The isomerization treatment can be performed by irradiating the liquid crystal composition with light through a patterning mask having a plurality of regions with different light transmittances in a plane.

A method of producing the patterning mask is not particularly limited, and may be a method of performing printing on a base material or a method of vapor-depositing a metal, such as chromium on a base material.

The wavelength of the emitted light is preferably appropriately changed according to the absorption wavelength of the photoisomerization optically active compound.

The patterning mask is described in, for example, paragraphs “0015” to “0016”, “0240”, and “0242” of WO2020/122245A. The contents of the above-described document are incorporated in the present specification by reference. In the isomerization, two or more patterning masks may be used.

In the photoisomerization, it is preferable that the liquid crystal composition is irradiated with light in a wavelength range in which a polymerization initiation species is not generated from a photopolymerization initiator. For example, the patterning mask that transmits light in a wavelength range in which the photoisomerization of a photoisomerization optically active compound occurs and shields light in a wavelength range in which a polymerization initiation species is generated from a photopolymerization initiator is preferably used.

The light emitted to the liquid crystal composition is preferably light including a wavelength of 400 nm or less, more preferably light including a wavelength of 380 nm or less, and particularly preferably light including a wavelength of 310 nm to 360 nm.

The adjustment of the wavelength of light may be carried out by a known means and a known method. Examples of a method of adjusting the wavelength of light include a method of using an optical filter, a method of using two or more types of optical filters, and a method of using a light source having a specific wavelength.

The exposure amount is not particularly limited, and can be set to 0.1 mJ/cm² to 2,000 mJ/cm².

The emitted light is not particularly limited, but ultraviolet rays are preferable.

Examples of the light source include an ultra-high pressure mercury lamp, a high pressure mercury lamp, and a metal halide lamp. In addition, examples of the light source also include a light emitting diode capable of emitting light in a narrow wavelength range.

The photoisomerization is described in, for example, paragraphs “0014” to “0016” of WO2020/122245A. The contents of the above-described document are incorporated in the present specification by reference.

### —Support—

The support is preferably a resin support and more preferably a resin film.

Examples of the resin include polyethylene terephthalate (PET), polyethylene naphthalate (PEN), an acrylic resin, a urethane resin, a urethane-acrylic resin, polycarbonate (PC), acrylic-polycarbonate, polyolefin, triacetyl cellulose (TAC), a cycloolefin polymer (COP), and an acrylonitrile/butadiene/styrene copolymer (ABS resin).

From the viewpoint of strength and the like, the support is preferably a resin film containing at least one resin selected from the group consisting of polyethylene terephthalate, an acrylic resin, a urethane resin, a urethane-acrylic resin, polycarbonate, an acrylic-polycarbonate resin, and polypropylene, and more preferably a resin film containing at least one resin selected from the group consisting of an acrylic resin, polycarbonate, and an acrylic-polycarbonate resin.

The support may have a monolayer structure or a multilayer structure. Examples of the preferred laminated film include an acrylic resin/polycarbonate resin laminated film.

The support may contain an additive as necessary. Examples of the additive include a lubricant such as a mineral oil, a hydrocarbon, a fatty acid, an alcohol, a fatty acid ester, a fatty acid amide, a metal soap, a natural wax, or silicone, an inorganic flame retardant such as magnesium hydroxide or aluminum hydroxide, an organic flame retardant such as a halogen-based flame retardant or a phosphorus-based flame retardant, an organic or inorganic filler such as metal powder, talc, calcium carbonate, potassium titanate, glass fiber, carbon fiber, or wood powder, an additive such as an antioxidant, an ultraviolet inhibitor, a glidant, a dispersant, a coupling agent, a foaming agent, or a colorant, and an engineering plastic other than the above-mentioned resins, such as a polyolefin, polyester, polyacetal, polyamide, or polyphenylene ether resin.

From the viewpoint of strength, the thickness of the support is preferably 1 μm or more, more preferably 10 μm or more, still more preferably 20 μm or more, and particularly preferably 50 μm or more. From the viewpoint of moldability, the thickness of the support is preferably 500 μm or less, more preferably 450 μm or less, and particularly preferably 200 μm or less.

A support manufactured by a method known in the related art may be used or a commercially available support may be used as the support.

### —Undercoat Layer—

The film of the display device of the present disclosure may have an undercoat layer. As a result, a wave structure can be formed in the cholesteric liquid crystal layer formed by applying the liquid crystal composition to the surface of the undercoat layer and curing the liquid crystal composition. Accordingly, since the helical axes of the cholesteric liquid crystal compounds in the cholesteric liquid crystal layer are directed in various directions, light scattering properties can be imparted to the cholesteric liquid crystal layer, and the designability can be improved.

The surface energy of the undercoat layer is preferably 30 to 60 mN/m². As a result, light scattering properties imparted to the cholesteric liquid crystal layer can be improved.

The surface energies of the undercoat layer and the cholesteric liquid crystal layer are calculated from the equation of Owens and Wendt by measuring a contact angle of the undercoat layer with two types of solutions (water, methylene iodide, and the like) having different surface tensions.

In one embodiment, the undercoat layer is a cured product of a composition for an undercoat layer containing a polymerizable monomer. Since the polymerizable monomer has been described above, the description thereof will be omitted here. Among the above-described polymerizable monomers, from the viewpoint of imparting light scattering properties to the cholesteric liquid crystal layer, a polyfunctional acrylate or a polyfunctional methacrylate is preferable. The number of functional groups (the number of (meth)acryloyl groups) contained in the polyfunctional acrylate or polyfunctional methacrylate is preferably 2 to 8 and more preferably 2 to 6. In the present disclosure, the “(meth)acryloyl group” includes an acryloyl group and a methacryloyl group.

The molecular weight of the polymerizable monomer is not particularly limited, but is preferably 1,000 or less and more preferably 500 or less. The lower limit is not particularly limited, but can be 100 or more.

The composition for an undercoat layer may contain one or two or more kinds of polymerizable monomers.

The proportion of the content of the polymerizable monomer with respect to the total mass of the solid content of the composition for an undercoat layer is preferably 0.5% by mass to 10% by mass, and more preferably 1% by mass to 5% by mass.

The composition for an undercoat layer can contain a resin such as a (meth)acrylic resin, a polyvinyl alcohol resin, a polyolefin resin, a cycloolefin polymer resin, a polycarbonate resin, a polyurethane resin, a polystyrene resin, a polyimide resin, an epoxy resin, a polyester resin, or a polyether resin.

Among the above, from the viewpoint of imparting light scattering properties to the cholesteric liquid crystal layer, a (meth)acrylic resin is preferable, and a resin obtained by curing a polyfunctional (meth)acrylic monomer such as pentaerythritol triacrylate or pentaerythritol tetraacrylate is preferable.

The composition for an undercoat layer may contain one kind or two or more kinds of resins.

The proportion of the content of the polymerizable monomer with respect to the total mass of the solid content of the composition for an undercoat layer is preferably 50% by mass to 85% by mass, and more preferably 60% by mass to 80% by mass.

The composition for an undercoat layer may include the above-described polymerization initiator, the above-described solvent, a surfactant, a polymerization inhibitor, an antioxidant, an ultraviolet absorber, a light stabilizer, a colorant, metal oxide particles, and other materials.

In one embodiment, the undercoat layer can have the configuration described in JP2020-060627A.

The undercoat layer can be formed by applying a composition for an undercoat layer onto a support and curing the composition. Since the coating method and the curing method are the same as the method of forming the specific layer, the description thereof will be omitted here.

### (Micro LED Display)

The micro LED display is not particularly limited as long as it is equipped with the micro LED, and a known micro LED display in the related art can be used.

The length of one side of the micro LED is 100 μm or less, but may be 50 μm or less.

### (λ/4 Retardation Plate)

The λ/4 retardation plate converts an image of linearly polarized light into an image of circularly polarized light. Accordingly, the direction of the slow axis of the λ/4 retardation plate is set such that the image of linearly polarized light is converted into the image of circularly polarized light.

As the λ/4 retardation plate, various known λ/4 retardation plates having a phase difference of approximately ¼ wavelength at any wavelength of visible light can be used.

As the λ/4 retardation plate, for example, a λ/4 retardation plate having a phase difference of 100 nm to 180 nm at a wavelength of 550 nm is preferable, and a λ/4 retardation plate having a phase difference of 120 nm to 160 nm is more preferable.

As the λ/4 retardation plate, a retardation plate described in JP2012-18396A may be used. The contents of the above-described document are incorporated in the present specification by reference.

### (Polarizer)

The polarizer is a so-called linear polarizer having a function of converting light into specific linearly polarized light. The polarizer is not particularly limited, and an absorption type polarizer can be used.

As a type of the polarizer, a polarizer containing polyvinyl alcohol as a main component, which is usually used, can be used.

The thickness of the polarizer is not particularly limited, but is preferably 5 μm to 20 m, more preferably 3 μm to 15 μm, and still more preferably 2 μm to 10 μm. By reducing the thickness of the polarizer, it is possible not only to reduce a thickness of the display device, but also to further reduce a water content, and to improve a thermal durability.

As the polarizer, those described in JP5048120B, JP5143918B, JP5048120B, JP4691205B, JP4751481B, JP4751486B, and the like may be used. The contents of the above-described document are incorporated in the present specification by reference.

### (Other Layers and Other Members)

The display device of the present disclosure may include other layers. Examples of the other layers include a protective layer, a reflective layer, a self-repairing layer, an antistatic layer, an antifouling layer, an electromagnetic wave shielding layer, and a conductive layer. The other layers are formed, for example, by applying a composition containing the components of the other layers and, if necessary, drying the applied composition.

The display device of the present disclosure may include other members. The other members are not particularly limited, and known members used in display devices can be used.

The display device of the present disclosure can be manufactured by bonding a film and a micro LED display with an adhesive, a pressure sensitive adhesive, or the like known in the related art.

In a case where the display device according to the present disclosure includes a film, a λ/4 retardation plate, a polarizer, and a micro LED display in this order, the display device can be manufactured by bonding the respective constituent members with a conventionally known an adhesive, a pressure sensitive adhesive, or the like.

### EXAMPLES

Hereinafter, the present disclosure will be described in detail with reference to Examples. However, the present disclosure is not limited to the following Examples, and the contents (for example, raw materials, conditions, and methods) described in the following Examples may be appropriately modified within the scope of the object of the present disclosure. In the following description, unless otherwise specified, “%” means “% by mass”.

### Example 1

### [Preparation of Support]

As a support, a polyethylene terephthalate (PET) film (COSMOSHINE A4160, manufactured by TOYOBO Co., Ltd., film thickness: 100 μm) having an easy adhesion layer on one surface was prepared.

### [Formation of Undercoat Layer]

The surface of the support on the side where the easy adhesion layer was not provided was coated with a composition 1 for an undercoat layer having the following composition using a #4 wire bar coater. Thereafter, the coating film was dried at 80° C. for 120 seconds and irradiated with ultraviolet rays of 180 mJ/cm² using an ultraviolet irradiation device using a metal halide lamp (MAL625NAL, manufactured by GS Yuasa International Ltd.) at 25° C. to produce a support 1 with an undercoat layer.

### —Composition of Composition 1 for Undercoat Layer—

Tricyclodecane dimethanol dimethacrylate (manufactured by Shin-Nakamura Chemical Co., Ltd.): 75 parts by mass
KAYARAD PET30 (manufactured by Nippon Kayaku Co., Ltd.): 25 parts by mass
IRGACURE 907 (manufactured by Ciba-Geigy): 3 parts by mass
Photopolymerization initiator (KAYACURE DETX, manufactured by Nippon Kayaku Co., Ltd.): 1 part by mass
Surfactant 1 having structure shown below: 0.01 parts by mass
Organic solvent 1 (methyl ethyl ketone): 136 parts by mass
Organic solvent 2 (cyclohexanone): 156 parts by mass

### Surfactant 1: A Compound Shown Below

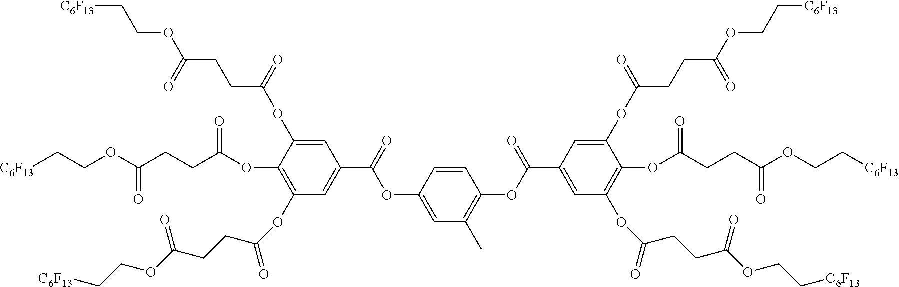

### [Formation of Cholesteric Liquid Crystal Layer]

A liquid crystal composition 1 having the following composition was prepared.

Rod-like liquid crystal compound 1 having structure shown below: 100 parts by mass
Chiral agent 1 (photosensitive chiral agent, compound having structure shown below): 7 parts by mass
Photopolymerization initiator (KAYACURE DETX, manufactured by Nippon Kayaku Co., Ltd.): 1 part by mass
Surfactant 1 (compound having structure shown above): 0.05 parts by mass
Surfactant 2 (compound having structure shown below): 0.055 parts by mass
Organic solvent (methyl ethyl ketone): 185 parts by mass

### Rod-Like Liquid Crystal Compound 1: Compound Shown Below

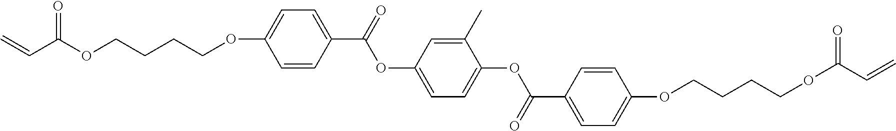 [SMILES: C=CC(=O)OCCCCOc1ccc(C(=O)Oc2ccc(OC(=O)c3ccc(OCCCCOC(=O)C=C)cc3)c(C)c2)cc1]

### Chiral Agent 1: Compound Shown Below

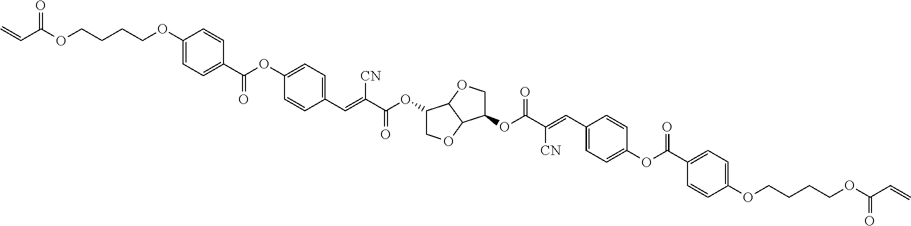

### Surfactant 2: Compound Shown Below

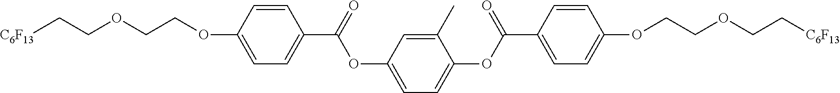

The surface of the support 1 with an undercoat layer on the undercoat layer side was coated with the liquid crystal composition 1 using a #5 wire bar coater. Thereafter, the coating film was dried at 80° C. for 120 seconds and irradiated with ultraviolet rays of 500 mJ/cm² using an ultraviolet irradiation device using a metal halide lamp (MAL625NAL, manufactured by GS Yuasa International Ltd.) at an oxygen concentration of 100 ppm or less and 80° C. to form a cholesteric liquid crystal layer, thereby obtaining a film 1. The thickness of the cholesteric liquid crystal layer was 2.5 μm. The surface energy of the undercoat layer was 40 mN/m².

### Example 2

A TAC (cellulose acylate) film was used as a support, and an alignment film and an optically anisotropic laver were formed thereon with reference to Examples (paragraphs “0272” to “0282”) of JP2012-18396A to prepare a λ/4 retardation plate. Re(550) and Rth(550) were 130 nm and −5 nm, respectively.

A polyvinyl alcohol layer was formed on the support with reference to JP5048120B, and the laminated film was stretched to obtain a polarizer.

The film 1, the λ/4 retardation plate, and the polarizer manufactured in Example 1 were bonded in this order using a pressure sensitive adhesive (SK Dyne, manufactured by Soken Chemical & Engineering Co., Ltd.) to obtain a laminate 1.

### Example 3

The support was prepared in the same manner as in Example 1.

### [Rubbing Treatment]

A rubbing treatment was performed on the surface of the support on a side where the easy adhesion layer was not provided. The rubbing treatment can be performed by rubbing the surface of the film containing a polymer as a main component with paper or cloth in a certain direction, and the rubbing treatment (rayon cloth, pressure of 0.1 kgf, rotation speed of 1,000 rpm, transportation speed of 10 m/min, number of times of rubbing: 1) was performed in a direction rotated counterclockwise by 3° with respect to the short side direction of the base material. In this manner, a support 2 in which an alignment layer was formed on a base material was prepared. The cholesteric liquid crystal layer was formed in the same manner as in Example 1 to obtain a film 2.

In the same manner as in Example 2, the film 2, the λ/4 retardation plate, and the polarizer were bonded in this order using a pressure sensitive adhesive (SK Dyne, manufactured by Soken Chemical & Engineering Co., Ltd.) to obtain a laminate 2. The thickness of the cholesteric liquid crystal layer was 2.5 μm.

### Example 4

A patterning mask was produced as follows.

A mask pattern (region A: 100% grayscale setting, region B: 50% grayscale setting) shown in the FIGURE was printed on an easy-bonding surface of a PET support (COSMOSHINE A4160, manufactured by Toyobo Co., Ltd., film thickness: 100 μm) using FUJI ZEROX Apeos Port-VII (manufactured by Fujifilm Business Innovation Corp.) in a grayscale to obtain a patterning mask.

Since an ink for mask printing is not applied to the region A printed in the case of the grayscale 100% setting, the region A does not absorb ultraviolet rays derived from the ink for mask printing. Therefore, the transmittance of ultraviolet rays in the region A is higher than that in the region B. As a result, the patterning mask having regions A and B having different transmittances of ultraviolet rays as shown in the FIGURE was produced.

In the FIGURE, a region A is indicated by reference numeral 10, and a region B is indicated by reference numeral 20.

The surface of the support 1 with an undercoat layer on the undercoat layer side was coated with the liquid crystal composition 1 using a #5 wire bar coater. Thereafter, the coating film was dried at 80° C. for 120 seconds.

Next, the patterning mask was closely attached to a surface of the support opposite to the surface to which the liquid crystal composition 1 was applied. The chiral agent was isomerized by irradiating the chiral agent with ultraviolet light having a wavelength of 365 nm at an illuminance of 65 mW and an exposure amount of 20 mJ/cm² using an ultraviolet (UV)-LED (manufactured by CCS Inc.) through the support and the patterning mask.

After the isomerization of the chiral agent, the coating film was irradiated with ultraviolet rays at 500 mJ/cm² (curing treatment) using an ultraviolet irradiation device using a metal halide lamp (MAL625NAL, manufactured by GS Yuasa International Ltd.) at an oxygen concentration of 100 ppm or less and 80° C., thereby forming a cholesteric liquid crystal layer, and a film 3 was obtained. The thickness of the cholesteric liquid crystal layer was 2.5 μm.

In the film 3, it can be seen that a region irradiated with light through the region A of the patterning mask shows blue color, a region irradiated with light through the region B shows green color, and the cholesteric liquid crystal layer has a plurality of regions having different maximum peak wavelengths of reflectivity in a plane.

The film 3, the λ/4 retardation plate produced in Example 2, and the polarizer produced in Example 2 were bonded in this order using a pressure sensitive adhesive (SK Dyne, manufactured by Soken Chemical & Engineering Co., Ltd.) to obtain a laminate 3.

### Example 5

Using a sputtering film forming apparatus (manufactured by Synchron Co., Ltd., RAS-1100C), a film of niobium oxide having a thickness of 100 nm and a film of silicon oxide having a thickness of 100 nm were alternately formed twice on an easy-bonding surface of a PET support (COSMOSHINE A4160, manufactured by TOYOBO Co., Ltd., film thickness: 100 μm) to obtain a film 4 (total of 4 layers).

### Comparative Example 1

A pattern (region A: 100% grayscale setting, region B: 50% grayscale setting) shown in the FIGURE was printed on an easy-bonding surface of a PET support (COSMOSHINE A4160, manufactured by TOYOBO Co., Ltd., film thickness: 100 μm) using FUJI ZEROX Apeos Port-VII (manufactured by Fujifilm Business Innovation Corp.) in a grayscale to obtain a printed support.

Using the technique described in JP2020-131666A, a film 5 was obtained by removing a part of the region A and the region B of the printed support without drilling holes in the PET support by irradiation with laser light (Nd:YAG laser having a wavelength of 1064 nm). The proportion of the sum of the areas of the removed the regions A and B to the area of the printed support (in Table 1, described as “opening ratio”) was set to 5%.

### Comparative Example 2

A film 6 was manufactured in the same manner as in Comparative Example 1, except that the opening ratio was changed to 40%.

### <Evaluation>

The following evaluations were performed using each of the films and each of the laminates obtained in Examples and Comparative Examples.

### <<Display Visibility Evaluation>>

A micro LED display (11-inch iPad Pro (registered trademark) third generation) was prepared.

Each film and each laminate were bonded to a surface of the micro LED display using a pressure sensitive adhesive (SK2057, manufactured by Soken Chemical & Engineering Co., Ltd.) to obtain a display device. For the film 1, a surface on the cholesteric liquid crystal layer side was bonded to the surface of the micro LED display. For the laminate 1 and the laminate 2, a surface on the polarizer side was bonded to the surface of the micro LED display. For the film 3 and the film 4, a surface on a printing side was bonded to the surface of the micro LED display. For the film 5, a surface on a sputtering film formation side was bonded to the surface of the micro LED display.

A visibility of the characters was evaluated by visual observation based on the following evaluation standards in a state in which the display of the micro LED display was set to an ON state (image display), and characters having a font size of 12 were displayed. The observation was performed at a position 1 μm away from the front of the display device.

### (Evaluation Standard)

A: Characters were able to be clearly recognized.

B: Characters were slightly blurred, but were recognizable.

C: Characters were blurred, and the recognition was difficult.

D: Characters could not be recognized.

### <<Designability Evaluation>>

A display device was manufactured in the same manner as in the display visibility evaluation.

The visibility of a decoration applied to the display device was evaluated based on the following evaluation standards in a state in which the display of the micro LED display was set to an OFF state (image not displayed).

The visibility evaluation of the decoration was performed in a state where the film or the laminate of the display device was irradiated with light (white light source) from an LED light source (LA-HDF108AA, manufactured by Hayashi-Reed Co., Ltd.). In the film of Example 1 and the laminates of Examples 2 and 3, selective reflectivity was confirmed, and the structural color was visually recognized.

It can be seen that the cholesteric liquid crystal layer included in the film or the laminate in which the structural color is visually recognized selectively reflects at least a part of light in a wavelength range of 380 nm to 780 nm.

### (Evaluation Standard)

A: Decoration could be clearly visually recognized, and excellent designability was confirmed.

B: Decoration was able to be visually recognized, or the decoration was difficult to visually recognize, and the designability could not be confirmed.

TABLE 1

| | | | | | Selective | | | | |
|---|---|---|---|---|---|---|---|---|---|
| | | | | | reflectivity | | | | |
| | | | | | of light in | | | | |
| | | | | | wavelength | Exhibition | | | |
| | | | | λ/4 | range of | of | | | |
| | Undercoat | | Polarizing | retardation | 380 nm to | structural | Opening | Display | |
| | layer | Patterning | plate | plate | 780 nm | color | ratio (%) | visibility | Designability |
| Example 1 | Present | Absent | Absent | Absent | Present | Present | 0 | B | A |
| Example 2 | Present | Absent | Present | Present | Present | Present | 0 | A | A |
| Example 3 | Absent | Absent | Present | Present | Present | Present | 0 | A | B |
| Example 4 | Present | Present | Present | Present | Present | Present | 0 | A | A |
| Example 5 | Absent | Absent | Absent | Absent | Present | Present | 0 | B | A |
| Comparative | Absent | Absent | Absent | Absent | Absent | Absent | 5 | D | A |
| Example 1 | | | | | | | | | |
| Comparative | Absent | Absent | Absent | Absent | Absent | Absent | 40 | C | B |
| Example 2 | | | | | | | | | |

From the results shown in Table 1, it was found that the display devices of Examples were more excellent in the visibility of the display in the image display state and the designability in the image non-display state than the display devices of Comparative Examples.

### EXPLANATION OF REFERENCES

10: region A
20: region B

The entire disclosure of Japanese Patent Application No. 2022-142397, filed Sep. 7, 2022, is incorporated into the present specification by reference.

All publications, patent applications, and technical standards described in the present specification are herein incorporated by reference to the same extent as in a case where each publication, each patent application, and each technical standard are specifically and individually indicated to be incorporated by reference.

What is claimed is:

1. A display device comprising:
a film including a layer that selectively reflects at least a part of light in a wavelength range of 380 nm to 780 nm to exhibit a structural color; and
a micro LED display.

2. The display device according to claim 1, further comprising:
a λ/4 retardation plate; and
a polarizer,
wherein the film, the λ/4 retardation plate, the polarizer, and the micro LED display are provided in this order.

3. The display device according to claim 1,
wherein the layer exhibiting the structural color is a cholesteric liquid crystal layer.

4. The display device according to claim 1,
wherein the layer exhibiting the structural color has a plurality of regions having different maximum peak wavelengths of reflectivity in a plane.

5. The display device according to claim 1,
wherein the film further includes a support and an undercoat layer, and
the support, the undercoat layer, and the layer exhibiting the structural color are provided in this order.

6. The display device according to claim 5,
wherein the layer exhibiting the structural color is a cholesteric liquid crystal layer, and the undercoat layer is a layer imparting light scattering properties to the cholesteric liquid crystal layer.

7. The display device according to claim 5,
wherein a surface energy of the undercoat layer is 30 mN/m² to 60 mN/m².

8. The display device according to claim 1,
wherein a thickness of the layer exhibiting the structural color is 0.3 μm to 15 μm.

9. The display device according to claim 1,
wherein the film is a decorative film.
